(19) United States
(12) Patent Application Publication
(10) Pub. No.: US 2021/0165044 A1
(43) Pub. Date: Jun. 3, 2021

(54) FAILURE DIAGNOSIS METHOD AND MANAGEMENT APPARATUS FOR ENERGY STORAGE DEVICE

(71) Applicant: GS Yuasa International Ltd., Kyoto-shi (JP)

(72) Inventor: Masayuki IMURA, Kyoto-shi, Kyoto (JP)

(21) Appl. No.: 17/048,649

(22) PCT Filed: Apr. 19, 2019
(86) PCT No.: PCT/JP2019/016741

§ 371 Date: Oct. 19, 2020

(30) Foreign Application Priority Data
Apr. 23, 2018 (JP) 2018-082247

(51) Int. Cl. G01R 31/327; F02N 11/08; F02N 11/10

(52) U.S. Cl. CPC G01R 31/3275; G01R 31/3274; H02H 7/18; F02N 11/108; F02N 11/0862

(57) ABSTRACT

A failure diagnosis method for an engine starting system 1 in which a starting energy storage apparatus 11 for supplying electric power to a starter 10 and an auxiliary energy storage apparatus 12 are connected in parallel, the method including: a first detection step (S102) of detecting a direction of a current with a detection unit 19 in a state where a first relay 20 is open and a second relay 23 is closed during discharge of the starting energy storage apparatus 11, and a determination step (S103) of determining the failure of the first relay 20 based on a detection result of the first detection step.

### TECHNICAL FIELD

The present invention relates to a failure diagnosis method for a system in which an energy storage apparatus for supplying electric power to an electrical load and another power supply, which is one of an energy storage apparatus and a charger, are connected in parallel, and a management apparatus for an energy storage device.

### BACKGROUND ART

Patent Document 1 discloses an energy storage apparatus that includes a circuit breaker connected in series with an energy storage device, and opens the circuit breaker to protect the energy storage device from overcharge or overdischarge when the overcharge or overdischarge of the energy storage device is predicted. In this energy storage apparatus, when the circuit breaker is out of order, it may not be possible to protect the energy storage device from overcharge or overdischarge. Therefore, failure diagnosis of the circuit breaker has been performed.

Patent Document 2 describes a battery pack in which a first switch and a second switch are connected in parallel. In Patent Document 2, an open command signal is first transmitted to a first switch, and a close command signal is transmitted to a second switch, to acquire an open voltage VAD. Next, a close command signal is transmitted to the first switch, and an open command signal is transmitted to the second switch, to acquire an open voltage VAR The failure of the first switch is diagnosed from a voltage difference ΔV between those voltages.

Patent Document 3 discloses a battery pack including a plurality of switches connected in parallel to each other and a both-end voltage detection unit that outputs a both-end voltage detection signal corresponding to each of both-end voltages of the plurality of switches. In Patent Document 3, the plurality of switches are sequentially designated at different times, and open command signals are given, to determine a switch failure based on the both-end voltage detection signal when each of the open command signals is given.

### PRIOR ART DOCUMENTS

### Patent Documents

Patent Document 1: JP-A-2017-135834

Patent Document 2: International Publication No. 2016/103721

Patent Document 3: JP-A-2014-036556

### SUMMARY OF THE INVENTION

### Problems to be Solved by the Invention

The techniques disclosed in Patent Document 2 and Patent Document 3 are each on the assumption that only one energy storage apparatus is connected to an electrical load. According to the techniques described in these patent documents, when another power supply (energy storage apparatus or charger) of substantially the same voltage is connected in parallel to an energy storage apparatus that supplies electric power to the electrical load, the voltage does not fluctuate even when the circuit breaker is opened, and it may be impossible to determine the failure of the circuit breaker.

The present specification discloses a technique in which in a system where a first energy storage apparatus for supplying electric power to an electrical load and another power supply, which is one of a second energy storage apparatus and a charger, are connected in parallel, even when the voltage of the first energy storage apparatus and the voltage of another power supply are substantially the same, it is possible to more reliably diagnose the failure of a circuit breaker provided in the first energy storage apparatus.

### Means for Solving the Problems

A failure diagnosis method for a system in which a first energy storage apparatus that supplies electric power to an electrical load and another power supply that is one of a second energy storage apparatus and a charger are connected in parallel, the first energy storage apparatus including an energy storage device provided in a current path connecting a positive external terminal and a negative external terminal of the first energy storage device, detection unit that is provided in the current path and detects at least one of a current value of a current flowing through the energy storage device and a direction of the current, a first circuit breaker that is provided in the current path on a side opposite to the detection unit with reference to the energy storage device, or between the energy storage device and the detection unit, a bypass path provided in parallel with a section of the current path, the section including the energy storage device and the first circuit breaker and not including the detection unit, and a second circuit breaker provided in the bypass path. The failure diagnosis method includes: a first detection step of detecting at least one of a current value and a direction by the detection unit in a state where the first circuit breaker is open and the second circuit breaker is closed during discharge of the first energy storage apparatus; and a determination step of determining the failure of the first circuit breaker based on a detection result of the first detection step.

### ADVANTAGES OF THE INVENTION

Even when the voltage of the first energy storage apparatus and the voltage of another power supply are substantially the same, it is possible to more reliably diagnose the failure of the circuit breaker provided in the first energy storage apparatus.

### BRIEF DESCRIPTION OF THE DRAWINGS

FIG. 1 is a schematic diagram of an engine starting system according to a first embodiment (with a first relay closed and a second relay open).

FIG. 2 is a schematic diagram of the engine starting system (with the first relay open and the second relay closed).

FIG. 3 is a schematic diagram of the engine starting system (with the first relay and the second relay closed).

FIG. 4 is a flowchart of a failure diagnosis process for the first relay.

FIG. 5 is a flowchart of a failure diagnosis process for a first relay according to a second embodiment.

FIG. 6 is a schematic diagram of an engine starting system according to a third embodiment (with the first relay closed, the second relay open, and third to fifth relays closed).

FIG. 7 is a diagram showing the relationship between the combination of the opening and closing of each relay and the presence or absence and direction of the current.

FIG. 8 is a schematic diagram of an engine starting system according to another embodiment (with the first relay closed and the second relay open).

### MODE FOR CARRYING OUT THE INVENTION

### Summary of the Present Embodiment

A failure diagnosis method disclosed by the present specification is a failure diagnosis method for a system in which a first energy storage apparatus that supplies electric power to an electrical load and another power supply that is one of a second energy storage apparatus and a charger are connected in parallel, the first energy storage apparatus including an energy storage device provided in a current path connecting a positive external terminal and a negative external terminal of the first energy storage apparatus, detection unit that is provided in the current path and detects at least one of a current value of a current flowing through the energy storage device and a direction of the current, a first circuit breaker that is provided in the current path on a side opposite to the detection unit with reference to the energy storage device, or between the energy storage device and the detection unit, a bypass path provided in parallel with a section of the current path, the section including the energy storage device and the first circuit breaker and not including the detection unit, and a second circuit breaker provided in the bypass path. The failure diagnosis method includes: a first detection step of detecting at least one of a current value and a direction with the detection unit in a state where the first circuit breaker is open and the second circuit breaker is closed during discharge of the first energy storage apparatus; and a determination step of determining the failure of the first circuit breaker based on a detection result of the first detection step.

The first energy storage apparatus includes the bypass path provided in parallel with the section of the current path, the section including the energy storage device and the first circuit breaker and not including the detection unit With this configuration, upon diagnosis of the failure of the first circuit breaker during discharge of the first energy storage apparatus, even when the voltage of the first energy storage apparatus and the voltage of another power supply are substantially the same, the result of the detection by the detection unit differs between a case where the first circuit breaker is not out of order (when the first circuit breaker is opened) and a case where the first circuit breaker is out of order (when the first circuit breaker is not opened). In other words, the detection result varies between the case where the first circuit breaker is not out of order and the case where the first circuit breaker is out of order. Therefore, when the voltage of the first energy storage apparatus and the voltage of another power supply are substantially the same as in the conventional case, the failure of the first circuit breaker can be diagnosed more reliably than when the voltage does not fluctuate.

The detection unit may detect a direction of the current. In the determination step, when the direction detected in the first detection step is a charge direction in which the first energy storage apparatus is charged, it may be determined that the first circuit breaker is normal, and in the other cases, it is determined that the first circuit breaker is out of order.

Upon detection of the failure of the first circuit breaker during discharge, even when the voltage of the first energy storage apparatus and the voltage of another power supply are substantially the same, the direction of the current is reversed between the case where the first circuit breaker is out of order and the case where the first circuit breaker is not out of order. In other words, the detection result varies between the case where the first circuit breaker is out of order and the case where the first circuit breaker is not out of order. Therefore, the failure can be determined more reliably than when the voltage does not fluctuate as in the conventional case.

When the first circuit breaker is out of order, the current value may be smaller in a case where the current value detected by the detection unit may be 0 A (ampere) or a case where the direction cannot be determined. In this case, the direction cannot be determined, but in the failure diagnosis method described above, the failure is determined in a case except for the case where the detected direction is the charge direction (in a case where the detected direction is a discharge direction or the direction cannot be determined), so that the failure can be determined even when the direction cannot be determined.

The detection unit may detect a current value of the current. The failure diagnosis method may further include a second detection step of detecting a current value with the detection unit in a state where the first circuit breaker is closed and the second circuit breaker is open during discharge of the first energy storage apparatus. In the determination step, the failure of the first circuit breaker may be determined based on the current value detected in the first detection step and the current value detected in the second detection step.

In the first energy storage apparatus provided with the bypass path described above, even when the voltage of the first energy storage apparatus and the voltage of another power supply are substantially the same, a result of comparison between a current value detected during discharge of the first energy storage apparatus and a current value detected after the control so as to open the first circuit breaker and close the second circuit breaker differs between the case where the first circuit breaker is out of order and the case where the first circuit breaker is not out of order. In other words, the comparison result varies between the case where the first circuit breaker is not out of order and the case where the first circuit breaker is out of order. Therefore, the failure of the first circuit breaker can be diagnosed more reliably than when the voltage does not fluctuate as in the conventional case.

The system may be provided with a third circuit breaker in at least one of a current path connecting the first energy storage apparatus and the electrical load, a current path connecting another power supply and the electrical load, and a current path inside another power supply. The detection unit may detect a direction of the current, and in the determination step. When the direction detected in the first detection step is a charge direction in which the first energy storage apparatus is charged, it may be determined that both the first circuit breaker and the third circuit breaker are normal, and in the other cases, it may be determined that at least one of the first circuit breaker and the third circuit breaker is out of order.

According to the failure diagnosis method described above, not only the first circuit breaker provided in the first energy storage apparatus but also the third circuit breaker provided outside the first energy storage apparatus can diagnose the failure of the first energy storage apparatus.

Another power supply may be the second energy storage apparatus.

According to the failure diagnosis method described above, even when the first energy storage apparatus for supplying electric power to the electrical load and the second energy storage apparatus are connected in parallel, the failure of the first circuit breaker can be diagnosed.

Another power supply may have a voltage higher than a voltage of the first energy storage apparatus, and the system may include a step-down unit that steps down a voltage applied by another power supply.

The voltage of another power supply may be higher than that of the first energy storage apparatus as in an example where the voltage of the first energy storage apparatus is 12 V, and the voltage of another power supply may be 48 V. In this case, a voltage applied by another power supply may be stepped down to substantially the same voltage as that of the first energy storage apparatus by the step-down unit provided in the system. According to the above failure diagnosis method, even when the voltage of another power supply is stepped down to substantially the same voltage as that of the first energy storage apparatus, it is possible to more reliably diagnose the failure of the first circuit breaker.

A resistor or a constant current source may be provided in the bypass path.

According to the failure diagnosis method described above, it is possible to prevent the energy storage device from being short-circuited when the second circuit breaker is closed.

A management apparatus for an energy storage device disclosed in the present specification includes: a detection unit that is provided in the current path to which the energy storage device is connected and detects at least one of a current value of a current flowing through the energy storage device and a direction of the current; a first circuit breaker that is provided in the current path on a side opposite to the detection unit with reference to the energy storage device, or between the energy storage device and the detection unit; a bypass path provided in parallel with a section of the current path, the section including the energy storage device and the first circuit breaker and not including the detection unit; a second circuit breaker provided in the bypass path; and a management unit. The management unit executes a first detection step of detecting at least one of the current value and the direction with the detection unit in a state where the first circuit breaker is open and the second circuit breaker is closed during discharge of the energy storage device, and a determination step of determining the failure of the first circuit breaker based on a detection result of the first detection step.

According to the management apparatus described above, in the system where the first energy storage apparatus for supplying electric power to the electrical load and another power supply, which is one of the second energy storage apparatus and the charger, are connected in parallel, it is possible to more reliably diagnose the failure of the first circuit breaker even when the voltage of the first energy storage apparatus and the voltage of another power supply are substantially the same.

The techniques disclosed in the present specification can be realized in various modes such as an apparatus, a method, a computer program for realizing the apparatus or the method, and a recording medium on which the computer program is recorded.

### First Embodiment

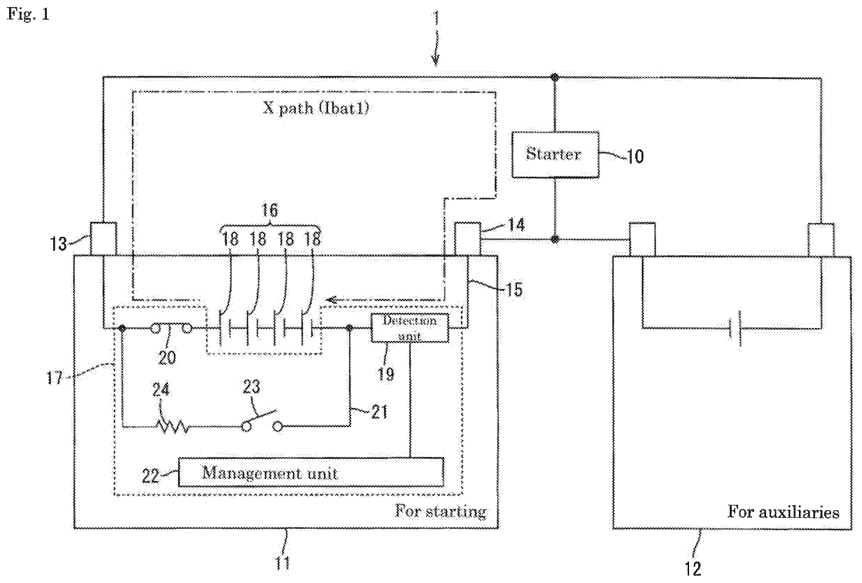

A first embodiment will be described with reference to FIGS. 1 to 4.

(1) Configuration of Engine Starting System

An engine starting system 1 (an example of the system) of the first embodiment will be described with reference to FIG. 1. The engine starting system 1 starts an engine of a vehicle. The engine starting system 1 includes a starter 10 (an example of the electrical load) for rotating a crankshaft of the engine, a starting energy storage apparatus 11 (an example of the first energy storage apparatus) for supplying electric power to the starter 10, and an auxiliary energy storage apparatus 12 (an example of the second energy storage apparatus and another power supply) for supplying electric power to auxiliary equipment (headlight, air conditioner, audio, etc.) mounted on the vehicle. The auxiliary energy storage apparatus 12 is connected in parallel with the starting energy storage apparatus 11, and electric power can be supplied from the auxiliary energy storage apparatus 12 to the starter 10.

In the present embodiment, it is assumed that the voltage of the starting energy storage apparatus 11 and the voltage of the auxiliary energy storage apparatus 12 are substantially the same. Specifically, it is assumed that the starter 10 has a load of 12 V, and both the starting energy storage apparatus 11 and the auxiliary energy storage apparatus 12 have a voltage of 12 V. The voltage of the starting energy storage apparatus 11 may be larger than that of the auxiliary energy storage apparatus 12, and the voltage of the auxiliary energy storage apparatus 12 may be larger than that of the starting energy storage apparatus 11.

(2) Electrical Configuration of Starting Energy Storage Apparatus

As shown in FIG. 1, the starting energy storage apparatus 11 includes a current path 15 connecting the positive external terminal 13 and the negative external terminal 14, an assembled battery 16 provided in the current path 15, and a battery management system 17 (an example of the management apparatus).

The assembled battery 16 has a plurality of energy storage devices 18 connected in series. Each energy storage device 18 is a rechargeable secondary battery, specifically, a lithium ion battery, for example. The plurality of energy storage devices 18 may be connected in parallel or may be connected in combination of series and parallel.

The BMS17 includes a detection unit 19 for detecting the direction of the current flowing through the energy storage device 18, a first relay 20 for interrupting the current path 15, a bypass path 21, a second relay 23, a resistor 24, and a management unit 22.

The detection unit 19 is provided in the current path 15, detects the direction of the current flowing through the energy storage device 18, and outputs the detected direction to the management unit 22.

The first relay 20 is provided between the positive external terminal 13 and the assembled battery 16 in the current path 15. The first relay 20 interrupts the current path 15 when overcharge or overdischarge of the energy storage device 18 is predicted.

The bypass path 21 is for diagnosing the failure of the first relay 20. The bypass path 21 is provided in parallel with a section of the current path 15, the section including the assembled battery 16 and the first relay 20 and not including the detection unit 19.

The second relay 23 and the resistor 24 are provided in the bypass path 21. The second relay 23 is of a normally open type, and is closed by the management unit 22 when the failure diagnosis of the first relay 20 is performed. The resistor 24 is for preventing the energy storage device 18 from being short-circuited when the second relay 23 is closed.

The management unit 22 is operated by electric power supplied from the assembled battery 16 and includes a central processing unit (CPU), a read-only memory (ROM), a random-access memory (RAM), and the like. The CPU executes a control program stored in the ROM to execute various processes such as protection of the energy storage device 18 and failure diagnosis of the first relay 20, which will be described later.

The management unit 22 may be provided with an application-specific integrated circuit (ASIC), a field-programmable gate array (FPGA), or the like, in place of the CPU or in addition to the CPU.

(3) Protection of Energy Storage Device

The management unit 22 estimates the state of charge (SOC) of the energy storage device 18, and when the estimated SOC is not less than a predetermined upper limit or not more than a predetermined lower limit, the first relay 20 is opened on the assumption that overcharge or overdischarge is predicted. As a result, the current path 15 is cut off, and the energy storage device 18 is protected from overcharge and overdischarge.

(4) Failure Diagnosis of First Relay

When the first relay 20 is out of order and is not opened, the energy storage device 18 cannot be protected from overcharge or overdischarge. Therefore, the management unit 22 performs the failure diagnosis of the first relay 20. The failure diagnosis of the first relay 20 is performed when the starting energy storage apparatus 11 is discharged. More specifically, the failure diagnosis of the first relay 20 is performed when a current (hereinafter referred to as discharge current) in the discharge direction stably flows from the starting energy storage apparatus 11. For example, when the engine of the vehicle is stopped, a discharge current stably flows from the starting energy storage apparatus 11. Hence the failure diagnosis of the first relay 20 is performed, for example, when the engine of the vehicle is stopped.

The discharge current of the starting energy storage apparatus 11 will be described with reference to FIG. 1. The discharge current of the starting energy storage apparatus 11 flows along a path X shown in FIG. 1. In FIG. 1, the current value when the discharge current stably flows is Ibat1. When a discharge current flows through the starting energy storage apparatus 11, the direction of the current detected by the detection unit 19 is the discharge direction.

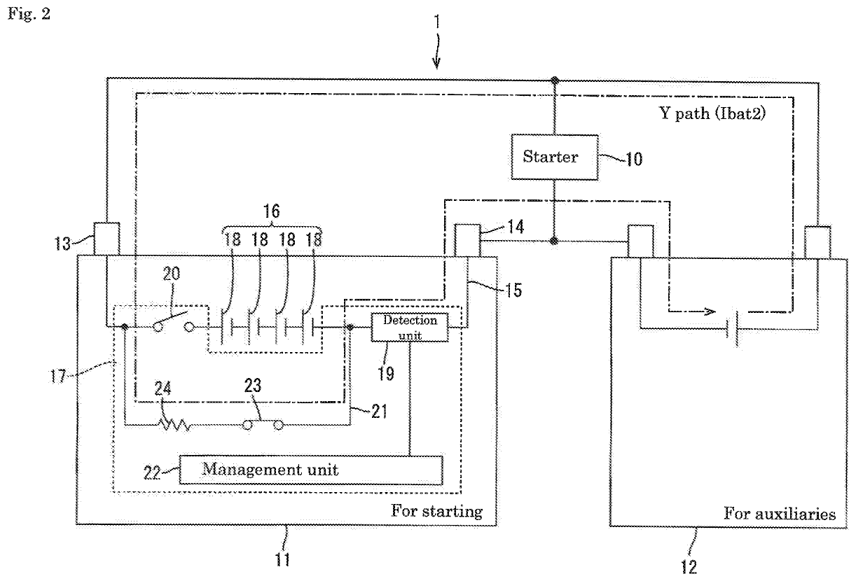

As shown in FIG. 2, in the failure diagnosis of the first relay 20, the management unit 22 performs control so as to open the first relay 20 and close the second relay 23. When the first relay 20 is not out of order (i.e., when the first relay 20 is open), as shown by a path Y in FIG. 2, a current Ibat2 flows from the auxiliary energy storage apparatus 12 to the starting energy storage apparatus 11. As shown by the path Y, the current Ibat2 flows through the bypass path 21 of the starting energy storage apparatus 11. The direction of the current Ibat2 is opposite to that of the current Ibat1, and the direction of the current detected by the detection unit 19 is the charge direction.

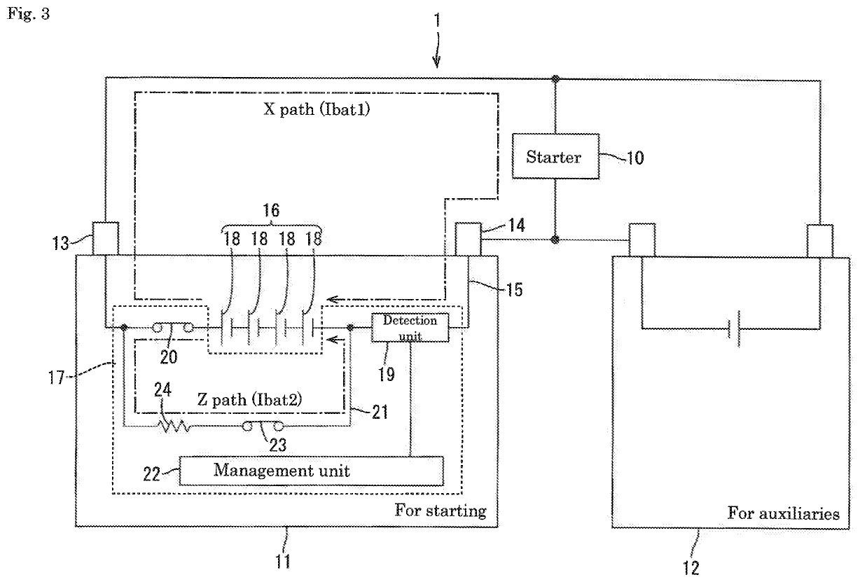

In contrast, as shown in FIG. 3, when the first relay 20 is out of order and does not open, the discharge current Ibat1 flows from the starting energy storage apparatus 11 to the starter 10 as shown by the path X. Further, as shown by the path Z, the discharge current Ibat2 flows from the starting energy storage apparatus 11 to the bypass path 21. Since the current Ibat1 flows through the detection unit 19, the direction of the current detected by the detection unit 19 becomes the discharge direction when the first relay 20 is out of order. Since the voltage of the starting energy storage apparatus 11 and the voltage of the auxiliary energy storage apparatus 12 are substantially the same, the current supplied by the auxiliary energy storage apparatus 12 does not appear in FIG. 3.

When the first relay 20 is not out of order, the direction of the current detected after the control so as to open the first relay 20 and close the second relay 23 is reversed.

Specifically, when the first relay 20 is not out of order, the detected direction is the charge direction, and when the first relay 20 is out of order, the detected direction is the discharge direction. Therefore, the failure of the first relay 20 can be determined by detecting the direction of the current.

When the first relay 20 is out of order, the current value detected by the detection unit 19 may be 0 A (ampere), or the current value may be so small that the direction cannot be determined. In that case, the direction cannot be determined. Therefore, the management unit 22 determines that the first relay 20 is out of order in a case except for the case where the detected direction is the charge direction (in a case where the detected direction is the discharge direction or the direction cannot be determined)

(5) Failure Diagnosis Process for First Relay

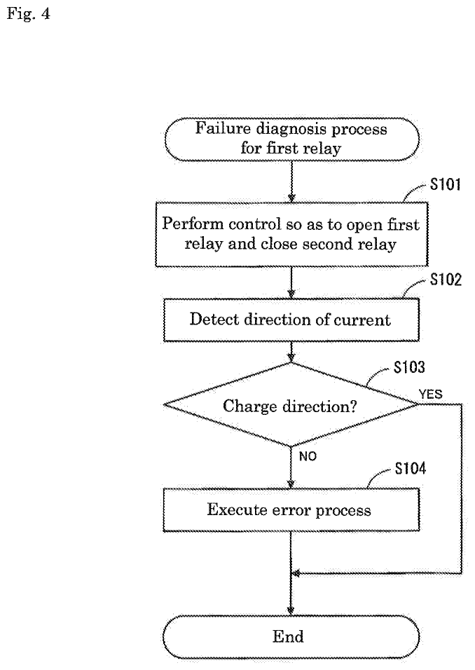

A failure diagnosis process for the first relay 20 executed by the management unit 22 will be described with reference to FIG. 4. The present process is performed, for example, when the engine of the vehicle is stopped.

In S101, the management unit 22 performs control so as to open the first relay 20 and close the second relay 23.

In S102, the management unit 22 detects the direction of the current with the detection unit 19 (an example of the first detection step).

In S103, the management unit 22 determines whether the direction detected in S102 is the charge direction or the other direction. In the case of the charge direction, it is determined that the first relay 20 is not out of order, and the present process ends. In the other cases, it is determined that the first relay 20 is out of order, and the process proceeds to S104 (an example of the determination step).

In S104, the management unit 22 executes a predetermined error process.

(5) Effects of Embodiment

According to the failure diagnosis method of the first embodiment, the starting energy storage apparatus 11 includes a bypass path 21 provided in parallel with the section of the current path 15, the section including the assembled battery 16 and the first relay 20 but not including the detection unit 19. With this configuration, upon diagnosis of the failure of the first relay 20 during discharge of the starting energy storage apparatus 11, even when the voltage of the starting energy storage apparatus 11 and the voltage of the auxiliary energy storage apparatus 12 are substantially the same, the result of the detection by the detection unit 19 differs between the case where the first relay 20 is not out of order (when the first relay 20 is opened) and the case where the first relay 20 is out of order (when the first relay 20 is not opened). In other words, the detection result varies between the case where the first relay 20 is not out of order and the case where the first relay 20 is out of order. Therefore, when the voltage of the starting energy storage apparatus 11 and the voltage of the auxiliary energy storage apparatus 12 are substantially the same as in the conventional case, the failure of the first relay 20 can be diagnosed more reliably than when the voltage does not fluctuate as in the conventional case.

According to the failure diagnosis method of the first embodiment, the failure of the first relay 20 is determined based on the direction of the current. Upon detection of the failure of the first relay 20 during discharge, even when the voltage of the starting energy storage apparatus 11 and the voltage of the auxiliary energy storage apparatus 12 are substantially the same, the direction of the current is reversed between the case where the first relay 20 is out of order and the case where the first relay 20 is not out of order. In other words, the detection result varies between the case where the first relay 20 is not out of order and the case where the first relay 20 is out of order. Therefore, the failure can be determined more reliably than when the voltage does not fluctuate as in the conventional case.

When the first relay 20 is out of order, the current value may be smaller in a case where the current value detected by the detection unit 19 may be 0 A (ampere) or a case where the direction cannot be determined. In this case, the direction cannot be determined, but in the failure diagnosis method of the first embodiment, the failure is determined in a case except for the case where the detected direction is the charge direction (in a case where the detected direction is the discharge direction or the direction cannot be determined), so that the failure can be determined even when the direction cannot be determined.

According to the failure diagnosis method of the first embodiment, the resistor 24 is provided in the bypass path 21, so that it is possible to prevent the energy storage device 18 from being short-circuited when the second relay 23 is closed.

According to the BMS17 of the first embodiment, in the engine starting system 1 in which the starting energy storage apparatus 11 and the auxiliary energy storage apparatus 12 are connected in parallel, even when the voltage of the starting energy storage apparatus 11 and the voltage of the auxiliary energy storage apparatus 12 are substantially the same, it is possible to more reliably diagnose the failure of the first relay 20.

### Second Embodiment

A second embodiment will be described with reference to FIGS. 2, 3, and 5. The engine starting system according to the second embodiment includes a current sensor as the detection unit 19 and diagnoses the failure of the first relay 20 from a current value measured by the current sensor. Similarly to the first embodiment, in the second embodiment as well, the failure diagnosis of the first relay 20 is performed when the discharge current stably flows from the starting energy storage apparatus 11.

As shown in FIG. 2, in the failure diagnosis of the first relay 20, the management unit 22 performs control so as to open the first relay 20 and close the second relay 23 when the discharge current stably flows from the starting energy storage apparatus 11.

As shown in FIG. 2, when the first relay 20 is not out of order, the current Ibat2 flows from the auxiliary energy storage apparatus 12 to the path Y. When the first relay 20 is not out of order, the current value (i.e., the current Ibat1 shown in FIG. 1) at the time of the discharge current stably flowing from the starting energy storage apparatus 11 does not match a current value (ibat2) detected after the control so as to open the first relay 20 and close the second relay 23.

In contrast, as shown in FIG. 3, when the first relay 20 is out of order and does not open, the current Ibat1 flows from the starting energy storage apparatus 11 to the path X. Since the detection unit 19 is on the path X, the current value Ibat1 is detected by the detection unit 19 when the first relay 20 is out of order. Thus, when the first relay 20 is out of order, the current value (ibat1) at the time of the discharge current stably flowing from the starting energy storage apparatus 11 matches the current value (ibat1) detected after the control so as to open the first relay 20 and close the second relay 23.

Therefore, the failure of the first relay 20 can be diagnosed by determining whether or not the current value detected after the control so as to open the first relay 20 and close the second relay 23 matches the current value (ibat1) detected when the discharge current stably flows from the starting energy storage apparatus 11.

(1) Failure Diagnosis Process for First Relay

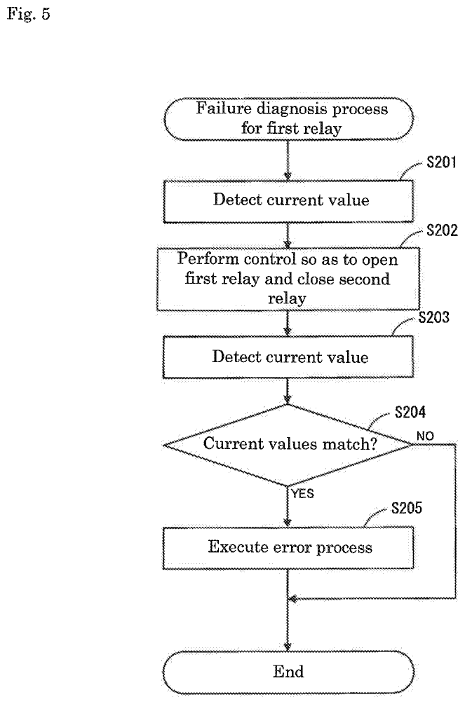

A failure diagnosis process for the first relay 20 according to the second embodiment will be described with reference to FIG. 5.

In S201, the management unit 22 detects a current value with the detection unit 19 (an example of the second detection step).

In S202, the management unit 22 performs control so as to open the first relay 20 and close the second relay 23.

In S203, the management unit 22 detects a current value with the detection unit 19 (an example of the first detection step).

In S204, the management unit 22 determines whether or not the current value detected in S201 and the current value detected in S203 match. When the current values do not match, it is determined that the first relay 20 is not out of order, and the present process ends. When the current values match, it is determined that the first relay 20 is out of order, and the process proceeds to S205 (an example of the determination step).

In S205, the management unit 22 executes a predetermined error process.

(2) Effects of the Embodiment

In the starting energy storage apparatus 11 provided with the bypass path 21, even when the voltage of the starting energy storage apparatus 11 and the voltage of auxiliary energy storage apparatus 12 are substantially the same, a result of comparison between a current value detected during discharge of the starting energy storage apparatus 11 and a current value detected after the control so as to open the first relay 20 and close the second relay 23 differs between a case where the first relay 20 is out of order and a case where the first relay 20 is not out of order. In other words, the comparison result varies between the case where the first relay 20 is not out of order and the case where the first relay 20 is out of order. Therefore, the failure of the first relay 20 can be diagnosed more reliably than when the voltage does not fluctuate as in the conventional case.

### Third Embodiment

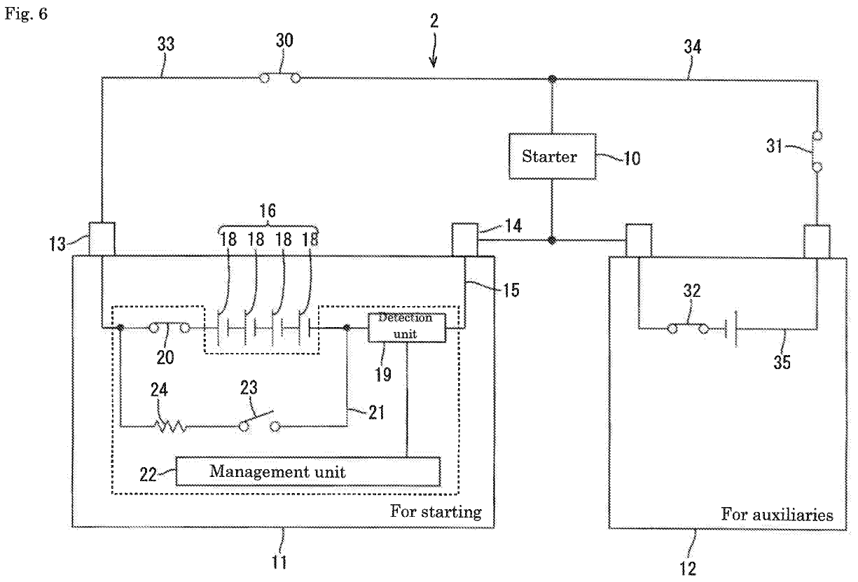

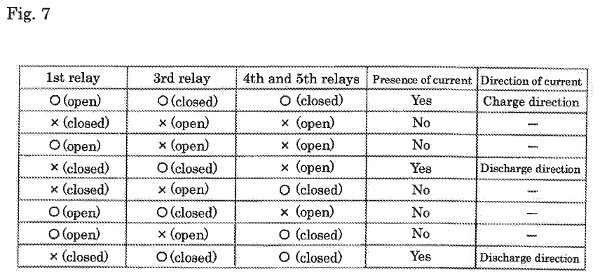

A third embodiment will be described with reference to FIGS. 6 to 7. As shown in FIG. 6, the engine starting system 2 according to the third embodiment includes a third relay 30, a fourth relay 31, and a fifth relay 32 in addition to the configuration of the first embodiment. Each of the third to fifth relays is an example of the third circuit breaker.

The third relay 30 is provided in a current path 33 connecting the starting energy storage apparatus 11 and the starter 10. The fourth relay 31 is provided in a current path 34 connecting the auxiliary energy storage apparatus 12 and the starter 10. The third relay 30 and the fourth relay 31 are opened and closed by an ECU of the vehicle.

The fifth relay 32 is provided in a current path 35 to which the energy storage device 18 is connected in the auxiliary energy storage apparatus 12. The fifth relay 32 is opened and closed by the management unit 22 (not shown) provided in the auxiliary energy storage apparatus 12.

The detection unit 19 according to the third embodiment can detect both the current value and the direction of the current.

The management unit 22 according to the third embodiment performs a failure diagnosis similar to that of the first embodiment to determine whether the first relay 20 and the third to fifth relays are all normal or at least one of these relays is out of order.

A specific description will be given with reference to FIG. 7. When the first relay 20 is opened at the time of performing failure diagnosis, the first relay 20 is normal. Therefore, the first relay 20 is normal (◯) when being open and abnormal (x) when being closed.

On the contrary, the third to fifth relays are normal when being closed, so that the third to fifth relays are normal (◯) when being closed and abnormal (x) when being open. In FIG. 7, when the relays 4 and 5 are “◯,” it means that both the fourth relay 31 and the fifth relay 32 are closed (normal), and when “x,” it means that at least one of the fourth relay 31 and the fifth relay 32 is open (abnormal).

As shown in FIG. 7, in a case where the same failure diagnosis as in the first embodiment is performed, when both the first relay 20 and the third to fifth relays are normal (◯), a current value larger than 0 amperes is detected by the detection unit 19 (i.e., the current is present), and the direction of the current detected by the detection unit 19 is the charge direction. In contrast, when at least one of these relays is abnormal (x), no current flows to the detection unit 19 (i.e., the current is absent), or the direction of the detected current is the discharge direction.

Therefore, the management unit 22 according to the third embodiment determines whether the first relay 20 and the third to fifth relays are all normal or at least one of these relays is out of order from the presence or absence of the current flowing through the detection unit 19 and the direction of the current.

According to the failure diagnosis method according to the third embodiment, not only the first relay 20 provided in the starting energy storage apparatus 11 but also the third to fifth relays provided outside the starting energy storage apparatus 11 can diagnose the failure of the starting energy storage apparatus 11.

### Other Embodiments

The techniques disclosed in the present specification are not limited to the embodiments described with reference to the above description and drawings, and the following embodiments, for example, are also the technical scope disclosed in the present specification.

(1) In the above embodiment, the second energy storage apparatus (auxiliary energy storage apparatus 12) has been described as an example of another power supply, but another power supply may be an external detachable charger for charging the first energy storage apparatus. For example, the external charger may be connected to a cigar socket of the vehicle, and the starting energy storage apparatus 11 may be charged by the connected charger. In this case as well, the failure of the first relay 20 in the starting energy storage apparatus 11 can be diagnosed similarly to the case where the second energy storage apparatus is connected.

(2) In the above embodiment, the auxiliary energy storage apparatus 12 has been described as the second energy storage apparatus, but the second energy storage apparatus may be a backup energy storage apparatus that supplies electric power to the electrical load (starter 10) in place of the starting energy storage apparatus 11 when the voltage of the starting energy storage apparatus 11 drops.

(3) In the above embodiment, the case has been described as an example where the voltage of the first energy storage apparatus (starting energy storage apparatus 11 in the first embodiment) and the voltage of another power supply (in the first embodiment, the auxiliary energy storage apparatus 12 is provided) are substantially the same. In contrast, the voltage of another power supply may be higher than the voltage of the first energy storage apparatus. The voltage of the auxiliary energy storage apparatus 12 may be higher than that of the starting energy storage apparatus 11 as in an example where the voltage of the starting energy storage apparatus 11 may be 12 V, and the voltage of the auxiliary energy storage apparatus 12 may be 24 V, 48 V, or higher. In this case, the voltage applied by the auxiliary energy storage apparatus 12 may be stepped down to substantially the same voltage as that of the starting energy storage apparatus 11 by a step-down unit (e.g., DC-to-DC converter) provided in the engine starting system. According to the failure diagnosis method described in the above embodiment, even when the voltage of the auxiliary energy storage apparatus 12 is stepped down to substantially the same voltage as the starting energy storage apparatus 11, it is possible to more reliably diagnose the failure of the first relay 20.

(4) In the embodiment described above, the case has been described as an example where the bypass path 21 is provided with the resistor 24, but a constant current source (e.g., constant current diode) may be provided instead of the resistor 24.

(5) In the third embodiment, the case has been described as an example where the engine starting system 2 has three relays of the third to fifth relays as the third circuit breakers, but the engine starting system 2 may have only one or two of these relays.

(6) In the above embodiment, the starter 10 has been described as an example of the electrical load, but the electrical load is not limited to the starter 10, and any equipment may be used so long as it consumes electric power. Although the engine starting system has been described as an example of the system in the above embodiment, the system may be any system so long as the first energy storage apparatus for supplying electric power to the electrical load and another power supply are connected in parallel.

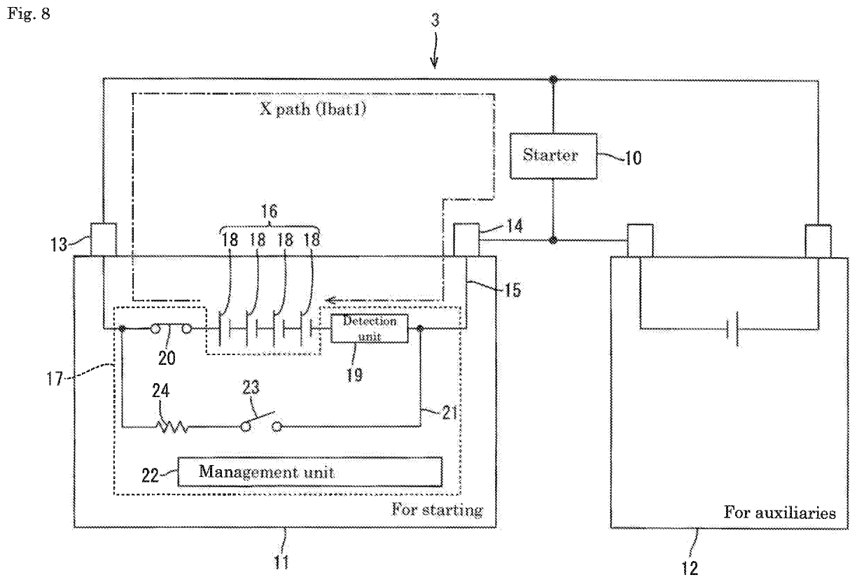

(7) In the second embodiment, the case has been described as an example where the bypass path 21 is provided in parallel with the section of the current path 15 of the starting energy storage apparatus 11, the section including the assembled battery 16 and the first relay 20 and not including the detection unit 19. In contrast, as in the engine starting system 3 shown in FIG. 8, the bypass path 21 may be provided in parallel with a section including the assembled battery 16, the first relay 20, and the detection unit 19 (current sensor). In this case, when the first relay 20 is normal, the first relay 20 is opened at the time of failure diagnosis, so that the current value measured by the current sensor is 0 A (ampere). In contrast, when the first relay 20 is out of order, the first relay 20 is not opened, so that the current value measured by the current sensor is larger than 0 A. Therefore, the failure of the first relay 20 can be determined based on whether or not the current value measured by the current sensor is 0 A.

(8) In the third embodiment, the case has been described as an example where the detection unit 19 can detect both the current value and the direction of the current, but only the direction of the current may be detected. Whether the first relay 20 and the third to fifth relays are all normal or at least one of these relays is out of order may be determined only from the direction of the current. Specifically, when the direction of the current is the charge direction, it may be determined that all the relays are normal, and when the direction of the current is not the charge direction (in a case where the detected direction is the discharge direction or the direction cannot be determined), it may be determined that at least one of the relays is out of order

(9) Although the lithium ion battery has been described as an example of the energy storage device 18 in the above embodiment, the energy storage device 18 may be a capacitor accompanied by an electrochemical reaction.

### DESCRIPTION OF REFERENCE SIGNS

1: engine starting system (example of system)

2: engine starting system (example of system)

10: starter (example of electrical load)

11: starting energy storage apparatus (example of first energy storage apparatus)

12: auxiliary energy storage apparatus (example of second energy storage apparatus and another power supply)

13: positive external terminal

14: negative external terminal

15: current path

17: battery management system (example of management apparatus)

18: energy storage device

19: detection unit

20: first relay (example of first circuit breaker)

21: bypass path

22: management unit

23: second relay (example of second circuit breaker)

24: resistor

30: third relay (example of third circuit breaker)

31: fourth relay (example of fourth circuit breaker)

32: fifth relay (example of fifth circuit breaker)

33: current path

34: current path

35: current path

1. A failure diagnosis method for a system in which a first energy storage apparatus that supplies electric power to an electrical load and another power supply that is one of a second energy storage apparatus and a charger are connected in parallel,
the first energy storage apparatus including:
an energy storage device provided in a current path connecting a positive external terminal and a negative external terminal of the first energy storage apparatus;
a detection unit that is provided in the current path and detects at least one of a current value of a current flowing in the energy storage device and a direction of the current;
a first circuit breaker that is provided in the current path on a side opposite to the detection unit with reference to the energy storage device, or between the energy storage device and the detection unit;
a bypass path provided in parallel with a section of the current path, the section including the energy storage device and the first circuit breaker and not including the detection unit; and
a second circuit breaker provided in the bypass path,
the failure diagnosis method comprising:
a first detection of detecting at least one of the current value and the direction with the detection unit in a state where the first circuit breaker is open and the second circuit breaker is closed during discharge of the first energy storage apparatus; and
a determination of determining failure of the first circuit breaker based on a detection result of the first detection.

2. The failure diagnosis method according to claim 1, wherein
the detection unit detects a direction of the current, and
in the determination, when the direction detected in the first detection is comprises a charge direction in which the first energy storage apparatus is charged, it is determined that the first circuit breaker is normal, and in the other cases, it is determined that the first circuit breaker is out of order.

3. The failure diagnosis method according to claim 1, wherein
the detection unit detects a current value of the current,
the failure diagnosis method further comprises a second detection of detecting a current value with the detection unit in a state where the first circuit breaker is closed and the second circuit breaker is open during discharge of the first energy storage apparatus, and
in the determination, the failure of the first circuit breaker is determined based on the current value detected in the first detection and the current value detected in the second detection.

4. The failure diagnosis method according to claim 1, wherein
the system is provided with a third circuit breaker in at least one of a current path connecting the first energy storage apparatus and the electrical load, a current path connecting the another power supply and the electrical load, and a current path inside the another power supply,
the detection unit detects a direction of the current, and
in the determination , when the direction detected in the first detection a charge direction in which the first energy storage apparatus is charged, it is determined that both the first circuit breaker and the third circuit breaker are normal, and in the other cases, it is determined that at least one of the first circuit breaker and the third circuit breaker is out of order.

5. The failure diagnosis method according to claim 1, wherein the another power supply comprises the second energy storage apparatus.

6. The failure diagnosis method according to claim 1, wherein
the another power supply has a voltage higher than a voltage of the first energy storage apparatus, and
the system includes a step-down unit that steps down a voltage applied by the another power supply.

7. The failure diagnosis method according to claim 1, wherein a resistor or a constant current source is provided in the bypass path.

8. A management apparatus for an energy storage device, comprising:
a detection unit that is provided in the current path to which the energy storage device is connected and detects at least one of a current value of a current flowing through the energy storage device and a direction of the current;
a first circuit breaker that is provided in the current path on a side opposite to the detection unit with reference to the energy storage device, or between the energy storage device and the detection unit;
a bypass path provided in parallel with a section of the current path, the section including the energy storage device and the first circuit breaker and not including the detection unit;
a second circuit breaker provided in the bypass path; and
a management unit,
wherein the management unit executes a first detection step of detecting at least one of the current value and the direction with the detection unit in a state where the first circuit breaker is open and the second circuit breaker is closed during discharge of the first energy storage device, and
a determination of determining failure of the first circuit breaker based on a detection result of the first detection.
